(19) United States
(12) Patent Application Publication
(10) Pub. No.: US 2025/0254794 A1
(43) Pub. Date: Aug. 7, 2025

(54) ELECTRONIC DEVICE

(71) Applicant: DENSO CORPORATION, Kariya-city (JP)

(72) Inventors: Hiroyoshi KUNIEDA, Kariya-city (JP); Yuichiro SASAKI, Kariya-city (JP); Kazuya HIRASAWA, Kariya-city (JP)

(21) Appl. No.: 18/976,998

(22) Filed: Dec. 11, 2024

(30) Foreign Application Priority Data
Feb. 2, 2024 (JP) 2024-014974

(51) Int. Cl. H05K 1/14; H05K 1/02; H05K 1/18

(52) U.S. Cl. CPC H05K 1/144; H05K 1/0204; H05K 1/181; H05K 2201/042; H05K 2201/10234; H05K 2201/10371

(57) ABSTRACT

An electronic device includes: a component board having a first surface on which a circuit component is mounted; a substrate on which the component board is mounted via a plurality of connecting members; and a lid member joined to the first surface of the component board to cover the circuit component. The component board has a second surface opposite to the first surface. Electrodes are arranged on the second surface and connected with the connecting members. The connecting members have a deformable connector where a distortion occurs due to thermal cycle. The first surface has an opposing region opposite to the electrode to which the deformable connector is connected, and the lid member is joined to the first surface of the component board within the opposing region.

### CROSS REFERENCE TO RELATED APPLICATION

This application is based on Japanese Patent Application No. 2024-014974 filed on Feb. 2, 2024, the disclosure of which is incorporated herein by reference.

### TECHNICAL FIELD

The present disclosure relates to an electronic device.

### BACKGROUND

As an electronic device, a ball grid array package has plural solder balls. The ball grid array package is mounted on a circuit board.

### SUMMARY

According to an aspect of the present disclosure, an electronic device includes a circuit component; a component board having a first surface on which the circuit component is mounted; a substrate on which the component board is mounted via connecting members; and a lid member joined to the first surface of the component board to cover the circuit component. Plural electrodes are arranged on the second surface of the component board opposite to the first surface and connected with the connecting members, which include a deformable connector subject to distortion due to thermal cycle. The lid member is joined to the first surface within an opposing region opposing the electrode to which the deformable connector is connected.

### BRIEF DESCRIPTION OF DRAWINGS

FIG. 1 is a plan view showing an electronic control device according to a first embodiment.

FIG. 2 is a plan view seen from an arrow direction Il in FIG. 1.

FIG. 3 is a cross-sectional view taken along a line III-III of FIG. 1.

FIG. 4 is a plan view seen from an arrow direction IV in FIG. 3.

FIG. 5 is a plan view seen from an arrow direction V in FIG. 3.

FIG. 6 is a cross-sectional view of an electronic control device according to a first modification.

FIG. 7 is a plan view illustrating a storage space of a lid member in the first modification.

FIG. 8 is a plan view illustrating a storage space of a lid member in a second modification.

FIG. 9 is a plan view illustrating a storage space of a lid member in a third modification.

FIG. 10 is a plan view illustrating a storage space of a lid member in a fourth modification.

FIG. 11 is a cross-sectional view of an electronic control device in a fifth modification at a room temperature.

FIG. 12 is a cross-sectional view of an electronic control device in a fifth modification at a low temperature.

FIG. 13 is a cross-sectional view of an electronic control device according to a second embodiment.

FIG. 14 is a cross-sectional view of an electronic control device in a sixth modification.

FIG. 15 is a cross-sectional view of an electronic control device according to a third embodiment.

### DETAILED DESCRIPTION

A ball grid array package has plural solder balls, and is mounted on a circuit board.

An electronic device includes: a circuit component having electrodes arranged thereon; a component board on which the circuit component is mounted; and a lid member mounted on the component board to cover the circuit component. The electronic device is mounted on a circuit board via connecting members. However, connection defects may occur in the connecting members due to deformation of the component board.

The present disclosure provides an electronic device in which connection failures are suppressed in the connecting members.

According to an aspect of the present disclosure, an electronic device includes a circuit component; a component board having a first surface on which the circuit component is mounted; a substrate on which the component board is mounted via connecting members; and a lid member joined to the first surface of the component board to cover the circuit component. Plural electrodes are arranged on the second surface of the component board opposite to the first surface and connected with the connecting members, which include a deformable connector subject to greater distortion due to thermal cycle. The lid member is joined to the first surface within an opposing region opposing the electrode to which the deformable connector is connected.

According to the electronic device, when the component board is mounted on the substrate, deformation of the component board in a direction away from the substrate is suppressed at the location where the lid member is joined. Therefore, the deformable connector can be restricted from a connection failure in the electronic device.

Embodiments for implementing the present disclosure will be described with reference to the drawings. In each embodiment, portions corresponding to those described in the preceding embodiment are denoted by the same reference numerals, and redundant descriptions will be omitted in some cases. In each embodiment, in a case where only a part of the configuration is described, the other part of the configuration may be applied with reference to the other embodiment described above. The present disclosure includes embodiments and modifications, which will be described later. Hereinafter, three directions perpendicular to each other are denoted as an X direction, a Y direction, and a Z direction.

### First Embodiment

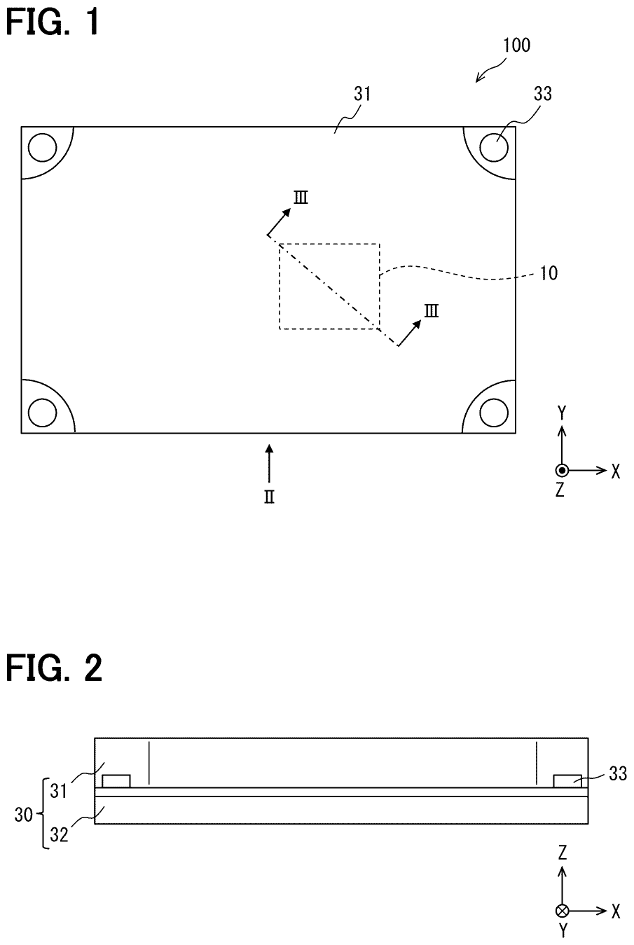

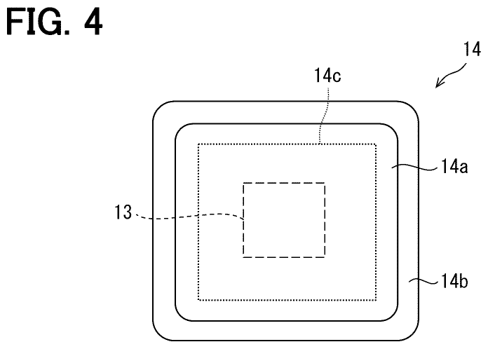

An electronic control device 100 according to a first embodiment will be described with reference to FIGS. 1 to 5. The electronic control device 100 is configured to be mountable on, for example, a mobile body. Examples of the mobile body include vehicles such as electric cars, hybrid cars, and fuel cell cars, flying objects such as electric vertical take-off and landing aircraft and drones, ships, construction machinery, and agricultural machinery. However, the electronic control device 100 can be mounted on an object other than the mobile body.

As shown in FIGS. 1, 2, and 3, the electronic control device 100 includes a module substrate 21m, a BGA chip 10 mounted on the module substrate 21m, and a case 30 that houses the module substrate 21m on which the BGA chip 10 is mounted. The electronic control device 100 includes solder balls 21 for electrically connecting the module substrate 21m and the BGA chip 10. The solder balls 21 correspond to connecting members. In this embodiment, the solder balls 21 are used as example of the connecting members. However, the connecting member is not limited to the solder ball 21, and may be silver paste, conductive adhesive, and the like. In the following, electrical connection will be referred to simply as connection. BGA is an abbreviation for Ball Grid Array.

The electronic control device 100 includes a second heat transfer member 42 for reducing the thermal resistance between the case 30 and the BGA chip 10. In other words, the electronic control device 100 includes the second heat transfer member 42 for improving the thermal conductivity between the case 30 and the BGA chip 10. In other words, the second heat transfer member 42 improves the heat dissipation performance of the BGA chip 10. Therefore, the heat of the BGA chip 10 is dissipated to the case 30 via the second heat transfer member 42.

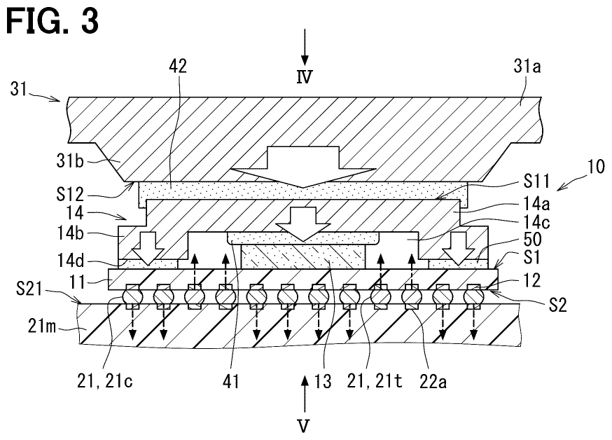

As shown in FIG. 3, the second heat transfer member 42 is disposed in contact with both the case 30 and the BGA chip 10. More specifically, the second heat transfer member 42 contacts an opposing surface S12 of the case 30 (the cover 31) and the top surface S11 of the BGA chip 10. The opposing surface S12 is a surface of the cover 31 that faces the BGA chip 10. The top surface S11 is a surface of the lid member 14 that faces the cover 31, which will be described later. The top surface S11 and the opposing surface S12 are disposed opposite to each other. Therefore, it can be said that the second heat transfer member 42 is pressurized by the top surface S11 and the opposing surface S12. In other words, the second heat transfer member 42 is provided between the lid member 14 and the cover 31 in a state of being compressed by the cover 31.

The second heat transfer member 42 may be a TIM such as silicone gel. TIM is an abbreviation for Thermal Interface Material. However, the second heat transfer member 42 may be an adhesive or the like.

As shown in FIGS. 1 and 2, the case 30 includes the cover 31, a base 32, and a screw 33. The case 30 provides a space for housing the BGA chip 10 and the module substrate 21m, by being formed by assembling the cover 31 and the base 32. The cover 31 and the base 32 are fixed to each other by the screw 33 in the assembled state. The screw 33 is provided, for example, at the four corners of the cover 31 and the base 32. The case 30 corresponds to a housing.

The fixing member for fixing the cover 31 to the base 32 is not limited to the screw 33. The cover 31 and the base 32 may be fixed to each other by a press-fit mechanism, a claw member, or the like.

As shown in FIG. 3, the cover 31 has a base portion 31a and a pressing portion 31b protruding from the base portion 31a. The pressing portion 31b is provided at a position facing the BGA chip 10. The pressing portion 31b protrudes toward the BGA chip 10 from the base portion 31a. The pressing portion 31b is disposed to oppose the lid member 14, which will be described later. The pressing portion 31b corresponds to a portion of the cover 31 disposed opposite the lid member 14.

The pressing portion 31b is provided to apply a compressive load to the second heat transfer member 42. A compressive load is applied to the second heat transfer member 42 in a blank arrow direction in FIG. 3. The reason for applying a compressive load to the second heat transfer member 42 is to make the second heat transfer member 42 thinner and thereby improve the heat dissipation performance of the BGA chip 10. Therefore, the pressing portion 31b applies a compressive load to the second heat transfer member 42, thereby thinning the second heat transfer member 42. The cover 31 is fixed to the base 32 by the screw 33 as described above. Therefore, a compressive load is continuously applied to the second heat transfer member 42. The blank arrow here is an arrow superimposed on the cover 31 in FIG. 3.

The module substrate 21m has a conductive wiring formed on an electrically insulating substrate. The module substrate 21m is a so-called wiring board. As shown in FIG. 3, the module substrate 21m has a mounting surface S21 on which the BGA chip 10 is mounted. Although not shown, the module substrate 21m has a back surface opposite to the mounting surface S21. In this embodiment, the module substrate 21m corresponds to a substrate.

The module substrate 21m includes a conductive mounting surface land 22a connected to the wiring. The mounting surface land 22a is exposed from the mounting surface S21. The mounting surface land 22a is connected with the solder ball 21. The mounting surface land 22a can be considered as an electrode of the module substrate 21m.

Plural mounting surface lands 22a are arranged on the module substrate 21m. The arrangement means that the lands are arranged two-dimensionally. That is, the module substrate 21m has the mounting surface lands 22a arranged thereon so that the BGA chip 10 can be mounted thereon. The module substrate 21m may have another mounting surface land 22a other than the arranged mounting surface lands 22a.

FIG. 3 illustrates the module substrate 21m on which one BGA chip 10 is mounted. However, another circuit element other than the BGA chip 10 may be mounted on the module substrate 21m. The circuit element may be switching elements such as MOSFETs, resistor elements, capacitor elements, coils, and the like. Furthermore, plural BGA chips 10 may be mounted on the module substrate 21m.

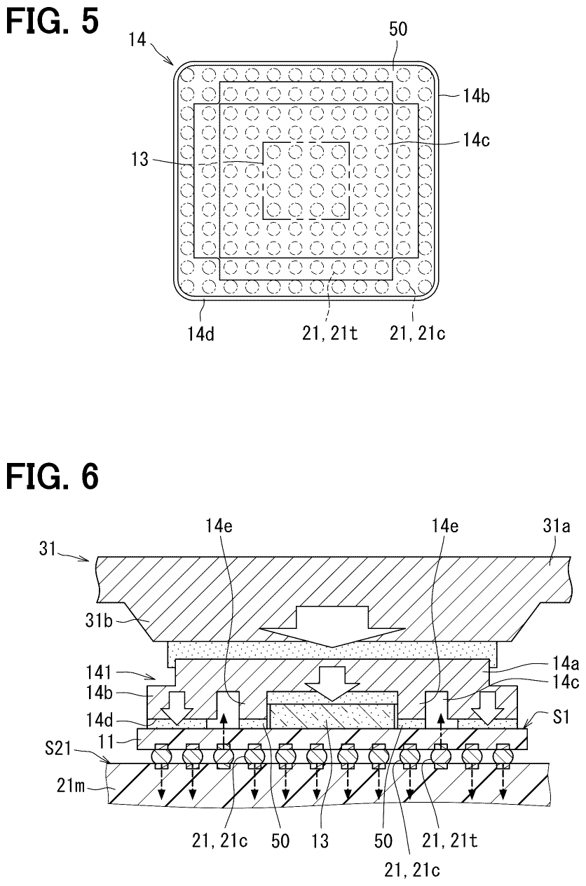

As shown in FIGS. 3, 4 and 5, the BGA chip 10 includes a BGA board 11, a BGA land 12, a semiconductor chip 13, and a lid member 14. The BGA chip 10 can be applied to, for example, a SoC (System on a Chip). In this embodiment, the semiconductor chip 13 corresponds to a circuit component, the BGA board 11 corresponds to a component board, and the BGA land 12 corresponds to an electrode. In this embodiment, the BGA chip 10 corresponds to an electronic device. In FIG. 5, the solder balls 21 are illustrated by dashed lines and double chain lines in order to show the relationship between the bonding area of the lid member 14 and the BGA board 11 and the state of the solder ball 21.

The BGA board 11 has a first surface S1 and a second surface S2. The BGA board 11 has a rectangular shape. Therefore, the first surface S1 and the second surface S2 have a rectangular shape.

The BGA board 11 is mounted on the module substrate 21m via the solder balls 21. The semiconductor chip 13 is mounted on the first surface S1. The BGA lands 12 are arranged on the second surface S2, and connected with the solder balls 21. The BGA lands 12 are arranged two-dimensionally, similar to the mounting surface lands 22a. Each of the BGA lands 12 is connected to the semiconductor chip 13.

As shown in FIG. 5, the solder balls 21 are arranged. The BGA lands 12 are connected to the solder balls 21 respectively. In other words, the BGA lands 12 are disposed opposite the solder balls 21. Therefore, the BGA lands 12 are arranged in the same manner as the solder balls 21. The solder balls 21 in FIG. 5 correspond to the BGA lands 12. In this manner, the solder balls 21 are connected to the BGA land 12 respectively. Therefore, the solder ball 21 can be considered as part of the BGA chip 10.

As shown in FIGS. 3, 4 and 5, the lid member 14 is bonded to the first surface S1 of the BGA board 11 to cover the semiconductor chip 13. The lid member 14 is mainly made of a metal such as aluminum. The lid member 14 is provided to improve the heat dissipation of the semiconductor chip 13.

The lid member 14 has a lid base 14a and an annular leg 14b protruding from the lid base 14a. The lid base 14a and the leg 14b of the lid member 14 define an accommodation space 14c for housing the semiconductor chip 13 therein. In this embodiment, the lid member 14 has a step formed between the lid base 14a and the leg 14b. However, the lid member 14 does not necessarily have to have the step.

The leg 14b has a pressing surface 14d facing the first surface S1. An adhesive 50 is provided between the pressing surface 14d and the first surface S1. That is, the BGA chip 10 is provided with the adhesive 50.

The lid member 14 is joined to the BGA board 11 by the adhesive 50. The lid member 14 is joined to the BGA board 11, thereby enabling the semiconductor chip 13 to be housed in a closed space. The lid member 14 and the BGA board 11 may be joined by a method other than using the adhesive 50.

As shown in FIG. 5, the adhesive 50 is provided in an annular shape. The adhesive 50 is provided only on a portion of the pressing surface 14d. In other words, the adhesive 50 is provided on the pressing surface 14d only at the location where the BGA board 11 is to be joined. The area of the lid member 14 where the adhesive 50 is provided is bonded to the BGA board 11. The area of the pressing surface 14d where the adhesive 50 is provided can also be referred to as a lid-side bonding area. On the other hand, the area on the first surface S1 where the adhesive 50 is provided can also be called a board-side bonding area. The lid-side bonding area faces the board-side bonding area.

In this embodiment, the board-side bonding area is provided in an area facing the BGA lands 12 provided at the four corners of the BGA board 11, and in an area facing the BGA lands 12 provided on the outermost periphery of the BGA board 11. The region facing the BGA land 12 includes not only the region facing the BGA land 12 but also the surrounding region of the BGA land 12.

The BGA land 12 provided at the four corners of the BGA board 11 can also be called four corner lands. The four corner lands are the BGA lands 12 provided at each of the four corners on the second surface S2. The multiple BGA lands 12 provided on the outermost periphery of the BGA board 11 can also be called the outermost periphery lands. The outermost periphery lands are the BGA lands 12 provided on the annular edge of the second surface S2. The solder balls 21 connected to the four corner lands can also be called four corner solders. The solder balls 21 connected to the outermost periphery lands can also be called outermost periphery solder.

Each of the four corner lands may include one BGA land 12 provided at the corner and three BGA lands 12 adjacent to the one BGA land 12. The BGA lands 12 other than the four corner lands and the outermost periphery lands are also called inner peripheral lands. Similarly, the solder balls 21 other than the four corner solder balls and the outermost periphery solder balls are referred to as inner peripheral solder balls.

The solder ball 21 has a linear expansion coefficient different from that of the BGA board 11 and the module substrate 21m. Therefore, the solder ball 21 may be distorted by thermal cycles. The magnitude of distortion of the solder ball 21 varies depending on the location. The four corner solders and the outermost periphery solder are more susceptible to distortion due to thermal cycles than the inner peripheral solder. The BGA chip 10 is subjected to thermal cycles during actual use and durability testing. The thermal cycles represent temperature changes repeatedly between high and low temperatures.

The lid member 14 is joined to the opposing area of the first surface S1 opposite the four corner lands and the outermost periphery lands. The four corner lands are the BGA lands 12 to which the four corner solder balls 21 are connected, which are subject to greater distortion due to thermal cycles. Similarly, the outermost periphery lands are the BGA lands 12 to which the outermost solder balls 21 subject to the greatest distortion due to thermal cycles are connected. The four corner solders and the outermost periphery solders correspond to a deformable connector. The solder balls 21 connected to the four corner lands and the outermost periphery lands are more likely to become the deformable connector than the other solder balls 21.

In this manner, in this embodiment, the four corner lands and the outermost periphery lands are used as an example of the BGA lands 12 to which the deformable connector is connected. However, the present disclosure is not limited to this. The BGA land 12 to which the deformable connector is connected is provided at least at one of the four corners of the BGA board 11, the outermost periphery of the BGA board 11, and a position facing the external periphery of the semiconductor chip 13. Moreover, the deformable connector is the solder ball 21 connected to at least one of the four corner lands, the outermost periphery lands, and the peripheral lands which will be described later.

The BGA chip 10 has a first heat transfer member 41 provided between the semiconductor chip 13 and the lid member 14. The first heat transfer member 41 is provided in a state of compressed by the lid member 14 in the blank arrow direction of FIG. 3 by joining the lid member 14 to the BGA board 11. The blank arrow here is shown superimposed on the lid base 14a. The first heat transfer member 41 may be provided between the semiconductor chip 13 and the lid member 14 in a state of being compressed from the lid member 14 by a compressive load on the second heat transfer member 42.

The leg 14b presses the BGA board 11 by applying a compressive load to the second heat transfer member 42. That is, the leg 14b presses the BGA board 11 in the blank arrow direction of FIG. 3. In this case, the leg 14b presses the BGA board 11 in the area joined to the BGA board 11. The blank arrow here is superimposed on the leg 14b.

The first heat transfer member 41 may be made of the same material as the second heat transfer member 42. TIM is used as an example of material of the first heat transfer member 41 and the second heat transfer member 42. However, the first heat transfer member 41 and the second heat transfer member 42 may be made of different materials. For example, the first heat transfer member 41 may be an adhesive and the second heat transfer member 42 may be a silicone gel. In this embodiment, the first heat transfer member 41 corresponds to a heat transfer member.

The state of the solder ball 21 will be described with reference to FIGS. 3 and 5. The BGA chip 10 is subjected to a compressive load as described above. In this state, the solder balls 21 include a compression solder 21c to which a compressive load is applied and a tensile solder 21t to which a tensile load is applied. In FIG. 3, the compression solder 21c and the tension solder 21t are hatched differently to distinguish them from each other.

A compressive load is applied to the BGA board 11 at the locations where the leg 14b is joined and where the semiconductor chip 13 is mounted. In other words, when the semiconductor chip 13 is housed in the case 30, the portion where the leg 14b is joined and the portion where the semiconductor chip 13 is mounted are pressed by the cover 31 and subjected to a compressive load. On the other hand, in the BGA board 11, no compressive load is applied to the area where the leg 14b is joined and the surrounding area of the semiconductor chip 13. In addition, the area where no compressive load is applied can be said to an area where the compressive load is smaller than the areas where the compressive load is applied.

In other words, the BGA board 11 has some locations where a compressive load is applied and other locations where no compressive load is applied. Therefore, a portion of the BGA board 11 to which the compressive load is applied tends to deform toward the module substrate 21m, while the other portion to which the compressive load is not applied tends to deform away from the module substrate 21m. Furthermore, at the portion of the BGA board 11 to which the lid member 14 is joined, deformation in a direction away from the module substrate 21m is suppressed because the lid member 14 is joined.

As described above, the second surface S2 opposite to the portion where the leg 14b is joined is provided with the four corner solders and the outermost periphery solder. Therefore, a compressive load is applied to the four corner solders and the outermost periphery solder. The solder at the four corners and the outermost periphery can be regarded as the compression solder 21c. As shown by the double chain line in FIG. 5, the solder ball 21 in the area where the adhesive 50 is provided is the compression solder 21c.

The second surface S2 where no compressive load is applied has the solder balls 21 (the inner peripheral solder) other than the peripheral solder and the outermost periphery solder. Thus, a tensile load is applied to the inner peripheral solder. Therefore, the inner peripheral solder can be regarded as the tensile solder 21t. As indicated by the dashed lines in FIG. 5, the solder ball 21 in the area where the adhesive 50 is not provided is the tensile solder 21t.

As shown in the dashed arrow direction of FIG. 3, a compressive load is applied to the compression solder 21c toward the module substrate 21m. On the other hand, a tensile load is applied to the tensile solder 21t in a direction away from the module substrate 21m. It can also be said that a stress is applied to the compression solder 21c in the direction toward the module substrate 21m. It can also be said that a stress is applied to the tensile solder 21t in a direction away from the module substrate 21m.

As described above, the BGA chip 10 has the lid member 14 joined to the BGA board 11. The lid member 14 is joined to the opposing area of the BGA land 12 to which the four corner solders and the outermost periphery solder are connected. Therefore, when the BGA board 11 is mounted on the module substrate 21m, deformation in the direction away from the module substrate 21m is suppressed at the portion where the lid member 14 is joined. Therefore, poor connection can be restricted at the four corner solders and the outermost periphery solder in the BGA chip 10. In other words, although the four corner solders and the outermost periphery solder are subject to greater distortion due to thermal cycle, the poor connection can be restricted. In other words, the life of the solder at the four corners and the outermost periphery can be improved in the BGA chip 10.

Furthermore, when the BGA chip 10 is housed in the case 30, a compressive load is applied to the solder at the four corners and the outermost periphery. Therefore, poor connection of the solder can be further suppressed at the four corners and the outermost periphery in the BGA chip 10.

As described above, the first embodiment is described. However, the present disclosure is not limited in any way to the above-mentioned embodiment, and various modifications can be performed without departing from the spirit of the present disclosure. The present disclosure is not limited to the combinations shown in the embodiments, but can be implemented by various combinations.

### First Modification

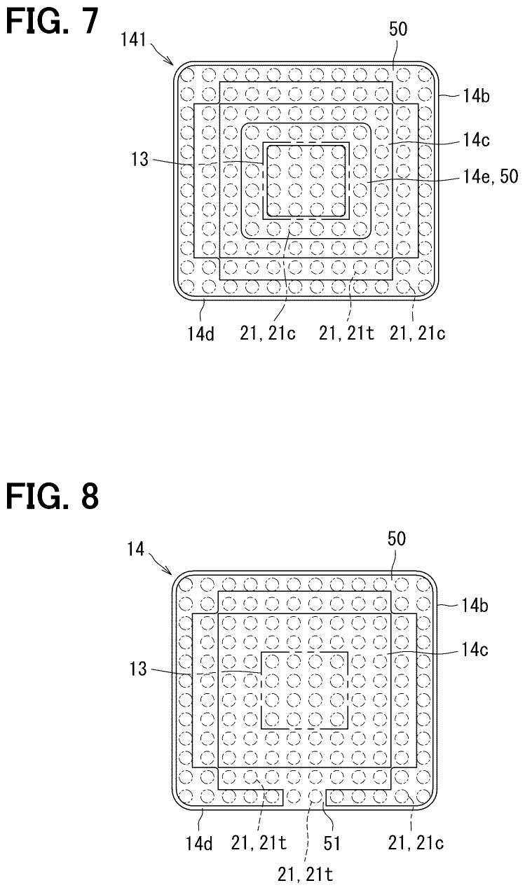

The BGA chip 10 of the first modification will be described with reference to FIGS. 6 and 7. In the first modification, the configuration of a lid member 141 differs from that of the above embodiment. FIG. 6 is a cross-sectional view corresponding to FIG. 3. FIG. 7 is a plan view corresponding to FIG. 5.

As shown in FIGS. 6 and 7, the lid member 141 has a lid protrusion 14e. The lid protrusion 14e is an annular projection that protrudes from the lid base 14a. The lid protrusion 14e is provided in the accommodation space 14c. The lid protrusion 14e is disposed on the external periphery of the semiconductor chip 13. That is, the lid protrusion 14e is disposed in a position surrounding the semiconductor chip 13. In this manner, the external periphery of the semiconductor chip 13 indicates an area surrounding the periphery of the semiconductor chip 13. Hereinafter, the external periphery of the semiconductor chip 13 will also be referred to as a chip periphery.

The lid protrusion 14e is joined to the BGA board 11 by the adhesive 50. That is, the lid member 141 is joined to the BGA board 11 not only at the leg 14b but also at the lid protrusion 14e. Therefore, the adhesive 50 is provided in two rings.

The BGA land 12 provided at position facing the chip periphery on the BGA board 11 can also be called peripheral land. The peripheral land is the BGA lands 12 adjacent to the opposing region of the semiconductor chip 13. Moreover, the solder balls 21 connected to the peripheral land can also be called a peripheral solder.

The semiconductor chip 13 has a different linear expansion coefficient from the BGA board 11. Therefore, the peripheral solder, like the four corner solders and the outermost periphery solder, is subject to large distortion due to thermal cycle. Therefore, the peripheral solder corresponds to a deformable connector.

However, the lid member 14 is bonded to the opposing area of the BGA land 12 to which the peripheral solder is connected. In other words, the peripheral solder is provided on the second surface S2 opposite to the portion to which the lid protrusion 14e is joined. Thus, a compressive load is applied to the peripheral solder. Therefore, the peripheral solder can be regarded as the compression solder 21c.

Therefore, when the BGA board 11 is mounted on the module substrate 21m, deformation in the direction away from the module substrate 21m is suppressed at the portion where the lid member 14 is joined. Therefore, poor connection of the peripheral solder can be restricted in the BGA chip 10.

### Second Modification

The BGA chip 10 of the second modification will be described with reference to FIG. 8. In the second modification, the joint between the lid member 14 and the BGA board 11 is different from that in the above embodiment. FIG. 8 is a plan view corresponding to FIG. 5.

The lid member 14 is partially joined to the outermost periphery of the BGA board 11. As shown in FIG. 8, the adhesive 50 is provided on the pressing surface 14d so that a passage 51 is formed. The area surrounded by the adhesive 50 communicates with the outside through the passage 51. The outside refers to a space outside the area surrounded by the adhesive 50. Moreover, the solder ball 21 facing the passage 51 becomes the tensile solder 21t.

This allows the BGA chip 10 to release gas generated when the adhesive 50 hardens to the outside. The passage 51 can be an exhaust path for discharging gas. The BGA chip 10 can achieve the same effects as the above embodiment.

The exhaust path may be configured to communicate between the area surrounded by the adhesive 50 and the outside. Therefore, the exhaust path may be provided in the BGA board 11 or the lid member 14. In this case, the adhesive 50 may be provided in a ring shape.

### Third Modification

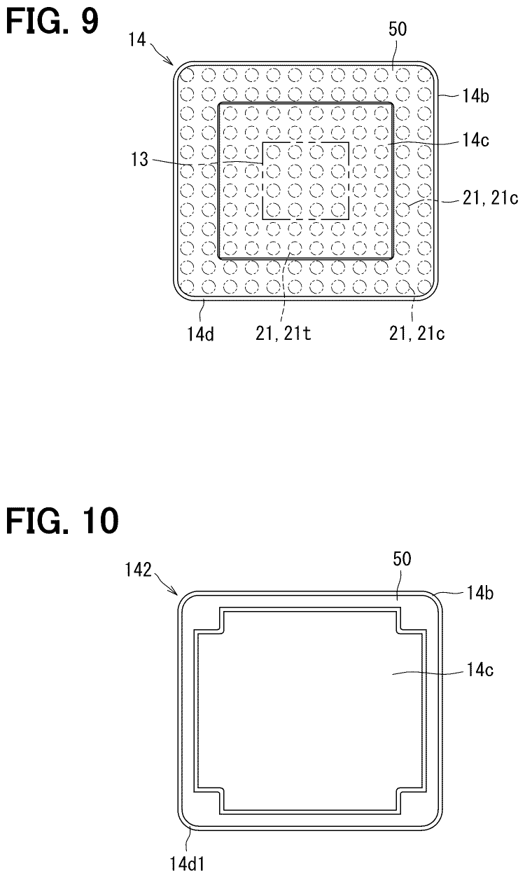

The BGA chip 10 of the third modification will be described with reference to FIG. 9. In the third modification, the area where the adhesive 50 is formed is different from that in the above embodiment. FIG. 9 is a plan view corresponding to FIG. 5.

As shown in FIG. 9, the adhesive 50 is provided over the entire pressing surface 14d. The solder ball 21 facing the adhesive 50 becomes the compression solder 21c. Therefore, the BGA chip 10 can increase the number of the compression solders 21c. Therefore, the BGA chip 10 can reduce the number of the solder balls 21 that may cause connection failure.

### Fourth Modification

The BGA chip 10 of the fourth modification will be described with reference to FIG. 10. In the fourth modification, the configuration of the lid member 142 differs from that of the above embodiment. FIG. 10 is a plan view corresponding to FIG. 5.

As shown in FIG. 10, the pressing surface 14d1 of the lid member 142 has a different shape from that of the above embodiment. The pressing surface 14d1 has the same shape as the area where the adhesive 50 is applied in the above embodiment. Moreover, the adhesive 50 is provided, for example, over the entire pressing surface 14d1. Therefore, the BGA chip 10 can achieve the same effects as the above embodiment.

### Fifth Modification

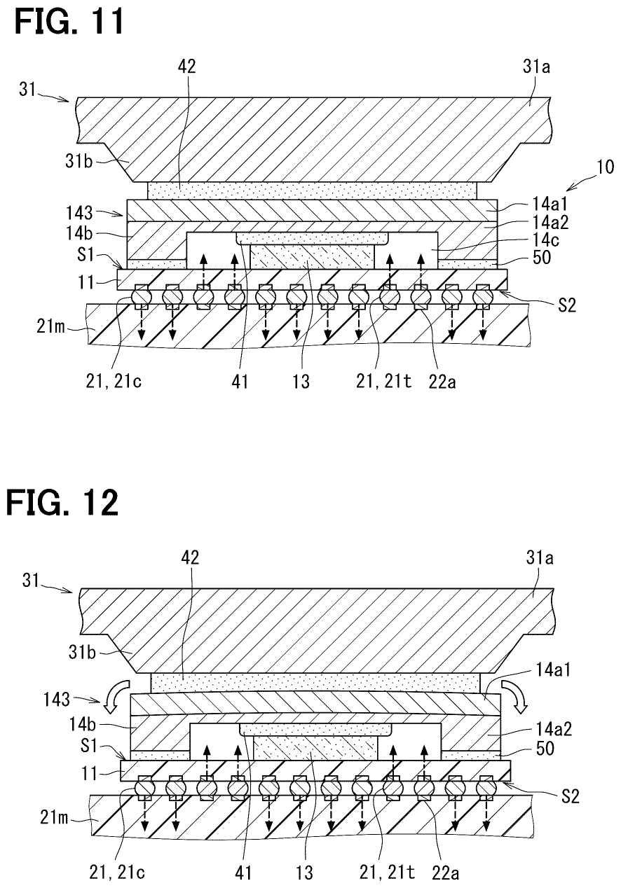

The BGA chip 10 of the fifth modification will be described with reference to FIGS. 11 and 12. In the fifth modification, the configuration of the lid member 143 is different from that of the above embodiment. FIGS. 11 and 12 are cross-sectional views corresponding to FIG. 3.

As shown in FIG. 11, the lid member 143 includes a first lid base 14a1 and a second lid base 14a2. The first lid base 14a1 is an upper member in a direction perpendicular to the first surface S1. The second lid base 14a2 is a lower member located in the direction perpendicular to the first surface S1. The terms “upper” and “lower” indicate the relative positional relationship between the first lid base 14a1 and the second lid base 14a2. The second lid base 14a2 is located closer to the BGA board 11 than the first lid base 14a1 is. The lid base is composed of the first lid base 14a1 and a part of the second lid base 14a2. The leg 14b is formed by the second lid base 14a2. The first lid base 14a1 corresponds to a first lid. The second lid base 14a2 corresponds to a second lid.

The first lid base 14a1 and the second lid base 14a2 are made of different materials. Furthermore, the first lid base 14a1 has a smaller linear expansion coefficient than the second lid base 14a2. The first lid base 14a1 is made of, for example, copper as a main component. The second lid base 14a2 is made mainly of aluminum, for example. In this manner, the lid member 143 has a bimetal structure.

As shown in FIG. 11, the lid member 143 does not deform when the ambient temperature is room temperature. Therefore, the top surface S11 of the first lid base 14a1 is flat.

As shown in FIG. 12, the lid member 143 deforms when the ambient temperature is low, because the first lid base 14a1 and the second lid base 14a2 have different linear expansion coefficients. Therefore, the lid member 143 deforms in the blank arrow direction so that the central portion of the top surface S11 becomes convex. Therefore, the lid member 143 applies stress to the solder ball 21 in the blank arrow direction. In other words, the lid member 143 applies stress to the solder balls 21 toward the module substrate 21m.

Therefore, in addition to the compressive load, stress due to the deformation of the lid member 143 is applied to the four corner solders and the outermost periphery solder. Therefore, in the BGA chip 10, poor connection of the solder can be restricted at the four corners and the outermost periphery more effectively. The room temperature is about 25° C. The low temperature is lower than the room temperature, at which a solder distortion occurs.

### Second Embodiment

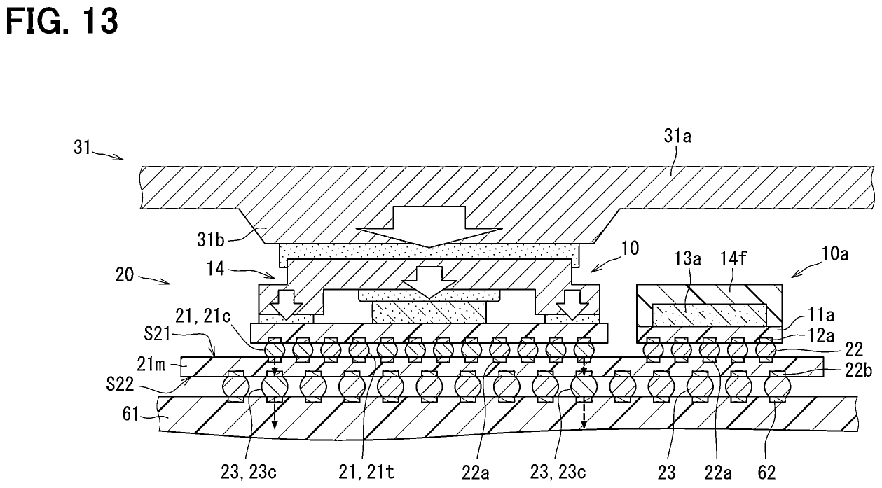

With reference to FIG. 13, an electronic control device 100 of a second embodiment will be described. The second embodiment differs from the above embodiment in that an MCM 20 and a motherboard 61 are provided. FIG. 13 is a cross-sectional view corresponding to FIG. 3. MCM is an abbreviation for Multi Chip Module.

As shown in FIG. 13, the electronic control device 100 includes the MCM 20 and the motherboard 61 on which the MCM 20 is mounted. Further, the electronic control device 100 includes the case 30, similar to the above embodiment.

The MCM 20 includes the BGA chips 10, 10a, and the module substrate 21m on which the BGA chips 10, 10a are mounted. The MCM 20 is mounted on the motherboard 61.

The BGA chip 10a has a similar configuration to the BGA chip 10. That is, the BGA chip 10a includes the BGA board 11a having the BGA land 12a, and the semiconductor chip 13a mounted on the BGA board 11a. However, the BGA chip 10a is provided with a sealing member 14f instead of the lid member 14. The sealing member 14f protects the semiconductor chip 13a. The sealing member 14f is in contact with the semiconductor chip 13a and covers the semiconductor chip 13a.

The BGA chip 10a is mounted on the mounting surface S21 of the module substrate 21m. The BGA chip 10a is connected to the mounting surface land 22a via the solder balls 22. The solder balls 22 are connected to the BGA lands 12a. The solder balls 22 may be considered as a part of the BGA chip 10a.

The module substrate 21m has a back surface opposite to the mounting surface S21. The back surface is an opposing surface S22 that faces the motherboard 61. The module substrate 21m has the back surface lands 22b in addition to the mounting surface lands 22a. The back surface land 22b is connected to the wiring of the module substrate 21m and is exposed from the opposing surface S22. In addition, the multiple back surface lands 22b are arranged on the opposing surface S22. The back surface land 22b is connected to the solder ball 23. The module substrate 21m is mounted on the motherboard 61 via the solder balls 23.

In this embodiment, the module substrate 21m corresponds to a substrate. In this embodiment, the BGA chip 10, the solder balls 21, and the module substrate 21m can be considered to be included in an electronic device. That is, the electronic device in this embodiment includes the BGA chip 10, the solder balls 21, and the module substrate 21m.

The motherboard 61 is an electrically insulating substrate on which conductive wiring is formed. The motherboard 61 includes a conductive motherland 62 connected to the wiring. The motherboard 61 includes the plural motherlands 62. The motherland 62 is exposed from the surface of the motherboard 61 on which the module substrate 21m is mounted. The motherlands 62 are arranged on the surface on which the module substrate 21m is mounted. The motherland 62 is connected to the solder ball 23. The motherboard 61 corresponds to a base board. The solder ball 23 corresponds to a base connecting member.

At least some of the solder balls 23 are provided in the opposing region of the outermost periphery solder. In other words, the solder balls 23 are provided immediately below the outermost periphery solder.

As a result, a reaction force is applied to the outermost periphery solder against the compressive load applied by the lid member 14. In other words, the outermost periphery solder is unlikely to move toward the solder balls 23 even if a compressive load is applied. Therefore, in the BGA chip 10, the compressive load applied to the outermost periphery solder is restricted from being reduced. Therefore, the BGA chip 10 is more likely to have a compressive load applied to the outermost periphery solder. The solder ball 23 immediately below the outermost periphery solder becomes the compression solder 23c.

The solder balls 23 may be provided in the opposing areas of the four corner solders or the peripheral solders. This makes it easier for a compressive load to be applied to the solder at the four corners and the peripheral solder of the BGA chip 10. The BGA chip 10 can achieve the same effects as the above embodiment.

In this embodiment, only a portion of the motherboard 61 on which one MCM 20 is mounted is shown. However, the motherboard 61 may have circuit elements mounted thereon other than the MCM 20. Furthermore, the motherboard 61 may have plural MCMs 20 mounted thereon.

### Sixth Modification

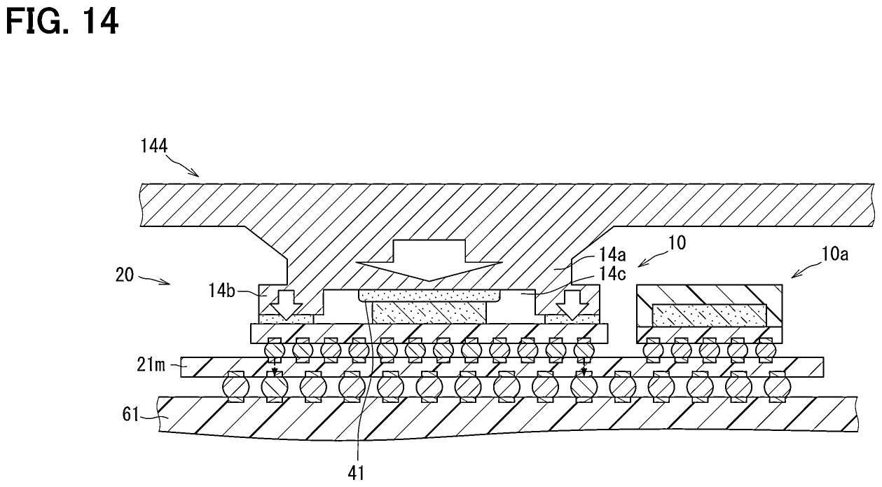

With reference to FIG. 14, an electronic control device of a sixth modification will be described. In the sixth modification, the configuration of the lid member 144 is different from that of the second embodiment. FIG. 14 is a cross-sectional view corresponding to FIG. 3.

As shown in FIG. 14, the lid member 144 is configured as an integral part with the case 30 (the cover 31) seamlessly. The lid member 144 can be considered as a part of the case 30. The first heat transfer member 41 is provided between the lid member 144 and the semiconductor chip 13 in a state of being compressed by the lid member 144.

This allows the BGA chip 10 to apply a compressive load from the case 30 to the solder at the four corners and the outermost periphery without going through the lid member 14 or the second heat transfer member 42 which are separate members from the case 30. Therefore, the BGA chip 10 can improve the life of the solder at the four corners and the outermost periphery. The lid member 144 can also be applied to the first to fourth modifications.

### Third Embodiment

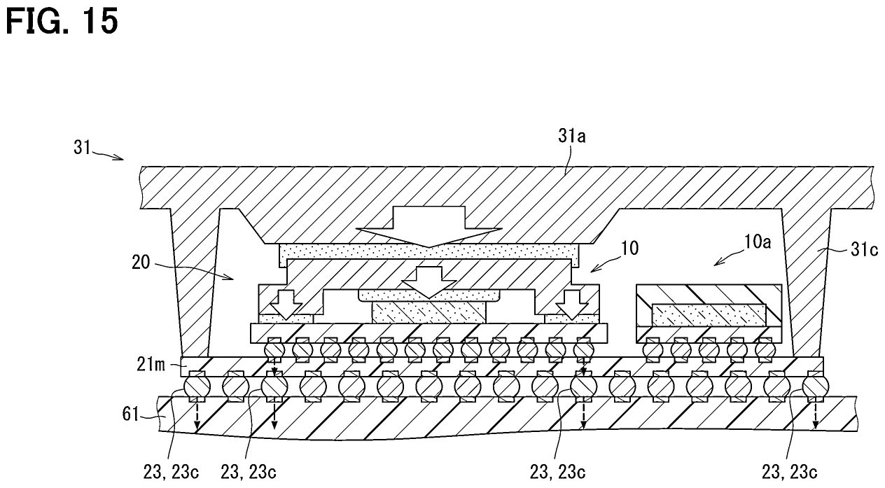

With reference to FIG. 15, an electronic control device 100 of a third embodiment will be described. In the third embodiment, the configuration of the cover 31 is different from that in the above embodiment. FIG. 15 is a cross-sectional view corresponding to FIG. 3.

As shown in FIG. 15, the cover 31 is provided with a cover protrusion 31c. The cover protrusion 31c protrudes from the base portion 31a. The cover protrusion 31c is in contact with the mounting surface S21 of the module substrate 21m. The cover protrusion 31c may be joined to the mounting surface S21 by the adhesive 50. The cover protrusion 31c presses the mounting surface S21 by the compressive load applied to the second heat transfer member 42. Here, the state in which the cover protrusion 31c is pressing against the mounting surface S21 is considered to be joined.

The electronic control device 100 can be considered to correspond to an electronic device. In this case, in the electronic control device 100, the MCM 20 corresponds to a circuit component, the module substrate 21m corresponds to a component board, the cover 31 corresponds to a lid member, and the back surface land 22b corresponds to an electrode. The solder balls 23 correspond to the connecting members, and the motherboard 61 corresponds to a substrate. The mounting surface S21 corresponds to a first surface, and the opposing surface S22 corresponds to a second surface. Furthermore, the cover protrusion 31c corresponds to a portion (the leg 14b) of the lid member 14 joined to the BGA board 11.

Therefore, the semiconductor chip 13, the BGA board 11, the lid member 14, and the BGA land 12 of the first embodiment can be replaced with the MCM 20, the module substrate 21m, the cover 31, and the back surface land 22b, respectively. Furthermore, the solder ball 21 and the module substrate 21m of the first embodiment can be replaced with the solder ball 23 and the motherboard 61, respectively. The first surface S1 and the second surface S2 in the first embodiment can be replaced with the mounting surface S21 and the opposing surface S22, respectively.

Furthermore, the leg 14b joined to the BGA board 11 in the first embodiment can be replaced with the cover protrusion 31c. That is, the cover protrusion 31c is joined to the mounting surface S21 within an opposing region of the back surface land 22b to which the deformable connector is connected. The deformable connector is subject to greater distortion due to thermal cycles among the multiple solder balls 23.

The solder balls 23 corresponding to the four corner solders are also called board four corner solders. The solder balls 23 corresponding to the outermost periphery solder are also called board outermost periphery solder. The solder balls 23 corresponding to the peripheral solder are also called board peripheral solder. The board four corners solder, the board outermost periphery solder, and the board peripheral solder correspond to a deformable connector.

The electronic control device 100 can achieve the same effects as the BGA chip 10 of the first embodiment. However, the solder balls to be improved in the life extension are the board four corners solder, the board outermost periphery solder, and the board peripheral solder.

In this embodiment, the electronic control device 100 serving as an electronic device can be regarded as being provided with the BGA chip 10 serving as an electronic device. That is, the case 30 houses the BGA board 11 (the BGA chip 10) on which the semiconductor chip 13 is mounted and to which the lid member 14 is joined, and the module substrate 21m on which the BGA board 11 is mounted. The module substrate 21m has the BGA board 11 mounted on the mounting surface S21, and is mounted on the motherboard 61 via the solder balls 23. The module substrate 21m has the second surface S2 opposing the motherboard 61, on which the back surface lands 22b are arranged, and the solder balls 23 are connected to the back surface lands 22b. The case 30 is joined to the mounting surface S21 in an opposing region of the back surface land 22b to which the deformable base connector, which is one of the multiple solder balls 23 subject to greater distortion due to thermal cycle, is connected.

In this case, the mounting surface S21 corresponds to a front surface, and the opposing surface S22 corresponds to a back surface. The solder balls 23 correspond to base connecting members, the motherboard 61 corresponds to a base board, and the back surface lands 22b correspond to base electrodes. The board four corners solder, the board outermost periphery solder, and the board peripheral solder correspond to a deformable base connector.

The electronic control device 100 can achieve the same effects as the BGA chip 10 of the first embodiment. Furthermore, the electronic control device 100 can also apply a compressive load to the solder balls 23. The life of the solder balls 23 can be improved. That is, in this case, the solder balls targeted for life extension are the solder ball 22 at the four corners and the solder ball 23 at the board four corners.

Although the present disclosure has been described in accordance with the embodiments, it is understood that the present disclosure is not limited to such embodiments or structures. The present disclosure encompasses various modifications and variations within the scope of equivalents. In addition, while various combinations and modes are described in the present disclosure, other combinations and modes including only one element, more elements, or less elements therein are also within the scope and spirit of the present disclosure.

What is claimed is:

1. An electronic device comprising:
a circuit component;
a component board having a first surface on which the circuit component is mounted;
a substrate on which the component board is mounted via a plurality of connecting members; and
a lid member joined to the first surface of the component board to cover the circuit component, wherein
the component board has a second surface opposite to the first surface,
a plurality of electrodes is arranged on the second surface and connected with the connecting members,
the connecting members have a deformable connector where a distortion, due to thermal cycle, is larger among the connecting members,
the first surface has an opposing region opposite to the electrode to which the deformable connector is connected, and
the lid member is joined to the opposing region.

2. The electronic device according to claim 1, wherein the electrode to which the deformable connector is connected is provided at least one of positions of four corners of the component board, an outermost periphery of the component board, and an external periphery of the circuit component.

3. The electronic device according to claim 1, further comprising an adhesive bonding the component board and the lid member.

4. The electronic device according to claim 1, wherein the lid member is joined to a part of an outermost periphery of the component board.

5. The electronic device according to claim 1, wherein
the lid member has a first lid and a second lid located on a lower side of the first lid in a direction perpendicular to the first surface,
the first lid and the second lid are made of different materials, and
the first lid has a linear expansion coefficient smaller than that of the second lid.

6. The electronic device according to claim 1, wherein
the substrate is mounted on a base board via a plurality of base connecting members, and
at least one of the plurality of base connecting members is provided within an opposing region of the deformable connector.

7. The electronic device according to claim 1, further comprising a housing that houses the component board on which the circuit component is mounted and to which the lid member is joined, and the substrate on which the component board is mounted, wherein
the substrate has a front surface on which the component board is mounted, and a back surface on which a base board is mounted via a plurality of base connecting members,
a plurality of base electrodes is arranged on the back surface opposing the base board,
the base connecting members are connected to the plurality of base electrodes,
the housing is bonded to the front surface of the substrate within an opposing region of the base electrode to which a deformable base connector is connected, and
the deformable base connector is subject to larger distortion, due to thermal cycle, among the plurality of base connecting members.

8. The electronic device according to claim 7, wherein the lid member is seamlessly formed with the housing.

9. The electronic device according to claim 1, further comprising a heat transfer member disposed between the circuit component and the lid member, in a state of being compressed by the lid member.

10. The electronic device according to claim 7, wherein
the housing includes an opposing portion disposed to oppose the lid member,
a first heat transfer member is provided between the circuit component and the lid member in a state of being compressed by the lid member, and
a second heat transfer member is provided between the lid member and the housing in a state of being compressed by the housing.
